(19) United States
(12) Patent Application Publication
(10) Pub. No.: US 2023/0317424 A1
(43) Pub. Date: Oct. 5, 2023

(54) EROSION RESISTANT PLASMA PROCESSING CHAMBER COMPONENTS

(71) Applicant: Lam Research Corporation, Fremont, CA (US)

(72) Inventors: Harmeet SINGH, Fremont, CA (US); Robin KOSHY, Fremont, CA (US); Adrian RADOCEA, Santa Clara, CA (US); Lin XU, Fremont, CA (US); Justin Charles CANNIFF, Santa Clara, CA (US); Simon GOSSELIN, San Bruno, CA (US)

(21) Appl. No.: 18/020,213

(22) PCT Filed: Aug. 17, 2021
(86) PCT No.: PCT/US2021/046372

§ 371 Date: Feb. 7, 2023

Related U.S. Application Data
(60) Provisional application No. 63/068,788, filed on Aug. 21, 2020.

(51) Int. Cl. H01J 37/32; H01L 21/67

(52) U.S. Cl. CPC H01J 37/32495; H01L 21/67069; H01J 37/32467; H01J 37/32807; H01J 2237/3341; H01J 37/321

(57) ABSTRACT

A component for use in a plasma processing chamber is provided. The component comprises a component body. A plasma facing surface of the component body is adapted to face a plasma in the plasma processing chamber. The plasma facing surface comprises 1) a layer of silicon doped with a dopant wherein the dopant is at least one of carbon, boron, tungsten, molybdenum, and tantalum, wherein the dopant has a concentration that ranges from 0.01% to 50% by mole percentage, or 2) a layer of carbon doped with a dopant wherein the dopant is at least one of silicon, boron, tungsten, molybdenum, and tantalum, wherein the dopant has a concentration that ranges from 0.01% to 50% by mole percentage, or 3) a layer consisting essentially of boron, or 4) a layer consisting essentially of tantalum.

### CROSS-REFERENCE TO RELATED APPLICATION

This application claims the benefit of priority of U.S. Application No. 63/068,788, filed Aug. 21, 2020, which is incorporated herein by reference for all purposes.

### BACKGROUND

The background description provided here is for the purpose of generally presenting the context of the disclosure. The information described in this background section, as well as aspects of the description that may not otherwise qualify as prior art at the time of filing, are neither expressly nor impliedly admitted as prior art against the present disclosure.

The present disclosure generally relates to the manufacturing of semiconductor devices. More specifically, the disclosure relates to plasma chamber components used in manufacturing semiconductor devices.

During semiconductor wafer processing, plasma processing chambers are used to process semiconductor devices. Plasma processing chambers are subjected to plasmas. The plasmas may degrade plasma facing surfaces of components of the plasma processing chamber. Some plasma-facing components on dielectric etch tools are primarily made of silicon. The components are made of silicon because dielectric etch tools significantly etch plasma-facing surfaces and the etching of silicon would not contaminate the plasma processing. Some components may be made of silicon carbide (SiC).

The components have a short lifetime due to various reasons. Such components undergo plasma etching until their dimensions shift to the point of negatively impacting on-wafer process performance. For example, the dimensions of an edge ring impact etch uniformity at a wafer edge. The dimensions of upper electrode gas holes impact gas delivery. In addition, surface morphology changes can cause a variety of issues including weak polymer adhesion resulting in on-wafer particles. On-wafer particles are solid particles that land on-wafer. Also, cosmetic issues occur as a result of plasma erosion that results in customer rejection of plasma-exposed parts. Components need to be replaced when their dimensions shift to the point of impacting the plasma processing.

In addition, components may have high manufacturing costs for various reasons. Components must be made of high purity materials to minimize wafer contamination risks. In addition, in order to meet wafer processing requirements, advanced chambers feature complex geometries that require tight dimensional tolerances. These features are often required to control on-wafer etch uniformity, and ensure robust interfaces with various plasma chamber subsystems for power delivery, temperature control, or gas delivery.

The high cost of manufacturing components combined with the short lifetimes results in a high cost of ownership to operate and use the plasma etch chamber to process wafers. The cost is high enough to be a significant fraction of the cost per bit.

### SUMMARY

To achieve the foregoing and in accordance with the purpose of the present disclosure, a component for use in a plasma processing chamber is provided. The component comprises a component body. A plasma facing surface of the component body is adapted to face a plasma in the plasma processing chamber. The plasma facing surface comprises 1) a layer of silicon doped with a dopant wherein the dopant is at least one of carbon, boron, tungsten, molybdenum, and tantalum, wherein the dopant has a concentration that ranges from 0.01% to 50% by mole percentage, or 2) a layer of carbon doped with a dopant wherein the dopant is at least one of silicon, boron, tungsten, molybdenum, and tantalum, wherein the dopant has a concentration that ranges from 0.01% to 50% by mole percentage, or 3) a layer consisting essentially of boron, or 4) a layer consisting essentially of tantalum.

In another manifestation, a method for providing a component for use in a plasma processing chamber is provided. A layer is formed on a plasma facing surface of the component wherein 1) the layer comprises silicon doped with a dopant wherein the dopant is at least one of carbon, boron, tungsten, molybdenum, and tantalum, wherein the dopant has a concentration that ranges from 0.01% to 50% by mole percentage, or wherein 2) the layer comprises carbon doped with a dopant wherein the dopant is at least one of silicon, boron, tungsten, molybdenum, and tantalum, wherein the dopant has a concentration that ranges from 0.01% to 50% by mole percentage, or wherein 3) the layer consists essentially of boron or tantalum.

In another manifestation, a component for use in a plasma processing chamber is provided. A component body has a plasma facing surface. A coating of at least one of boron, tungsten, molybdenum, and tantalum is on the plasma facing surface.

In another manifestation, a method for conditioning a component body with a semiconductor process facing surface for use in a semiconductor processing chamber is provided. The method comprises forming a layer, comprising at least one of boron, tungsten, molybdenum, and tantalum over the semiconductor process facing surface of the component body.

In another manifestation, a semiconductor processing chamber for processing substrates is provided. A substrate support is within a semiconductor process chamber. A gas inlet delivers gases into the semiconductor process chamber. A gas source provides the gases to the gas inlet. An electrode provides RF power in the semiconductor process chamber. At least one RF generator provides power to the electrode to form a plasma in the semiconductor processing chamber. A surface within the semiconductor process chamber is a semiconductor process facing surface wherein the semiconductor process facing surface comprises 1) a layer of silicon doped with a dopant wherein the dopant is at least one of carbon, boron, tungsten, molybdenum, and tantalum, wherein the dopant in has a concentration that ranges from 0.01% to 50% by mole percentage, or 2) a layer of carbon doped with a dopant wherein the dopant is at least one of silicon, boron, tungsten, molybdenum, and tantalum, wherein the dopant in has a concentration that ranges from 0.01% to 50% by mole percentage, or 3) a layer consisting essentially of boron, or 4) a layer consisting essentially of tantalum.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a top view of an embodiment.

FIG. 2 is a high level flow chart of an embodiment.

FIGS. 3A-C are schematic cross-sectional views of part of a component processed according to an embodiment.

FIG. 4 is a schematic view of a plasma processing chamber that may be used in an embodiment.

FIG. 5 is a schematic view of another embodiment.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Materials used in dielectric chambers must satisfy the constraint that they do not result in significant on-wafer contamination, either through direct deposition onto the wafer or the buildup of residue elsewhere in the chamber that may then be transported onto the wafer. For this reason, many materials such as aluminum or yttrium pose a significant risk due to the formation of non-volatile fluorides that result in on-wafer contamination. The elements in various embodiments for the composition of chamber components are boron (B), carbon (C), silicon (Si), tungsten (W), molybdenum (Mo), and tantalum (Ta), in order to meet the fluoride volatility constraint.

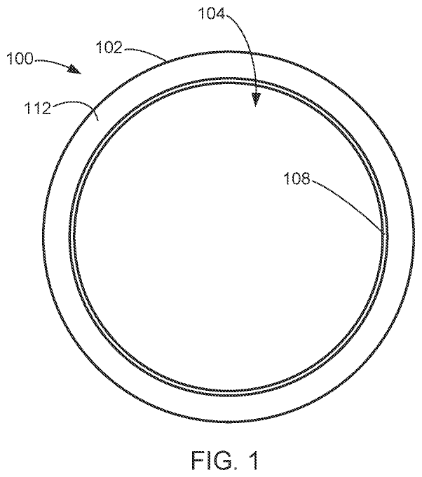

To facilitate understanding, FIG. 1 is a top view of an edge ring 100 according to an embodiment. The edge ring 100 comprises a component body 102. The component body 102 is in a ring shape with a central aperture 104. A central flange 108 is formed around the central aperture 104. A top surface 112 of the edge ring 100 is a semiconductor process facing surface when the edge ring 100 is used in a plasma processing chamber. In this example, the semiconductor process facing surface is a plasma facing surface in a semiconductor processing chamber, where the semiconductor processing chamber is a plasma processing chamber. In this embodiment, the component body 102 is formed by providing molten silicon and then doping the molten silicon with from 0.01% to 50% by mole percentage of a boron dopant. The molten silicon is then solidified either as a single crystal using the Czochralski method, or as a multicrystalline solid, or as an amorphous material that is cast in a mold. The solidified silicon may be machined and processed to form the edge ring 100 with the central aperture 104.

The resulting edge ring 100 would have a manufacturing cost about equal to the cost of making an edge ring out of silicon. However, the edge ring 100 of silicon doped with boron would be more resistant to fluorine plasma erosion and oxygen plasma erosion and physical sputtering erosion, so that the edge ring 100 would have a longer lifetime than an edge ring made out of pure silicon.

In various embodiments, the component body 102 may be made of silicon doped with a dopant where the dopant is at least one of carbon, boron, tungsten, molybdenum, and tantalum, where the dopant has a concentration that ranges from 0.01% to 50% by mole percentage or made of carbon doped with a dopant where the dopant is at least one of silicon, boron, tungsten, molybdenum, and tantalum, where the dopant in has a concentration that ranges from 0.01% to 50% by mole percentage. It should be noted that carbon doped with silicon is different than silicon carbide. Silicon carbide is made of molecules of silicon carbide. The ratio of silicon to carbon is silicon carbide is uniformly 1:1 throughout the structure. Carbon doped with silicon is a carbon structure, crystal, or matrix with silicon dopant. Silicon carbide is a silicon carbide structure, crystal, or matrix. Carbon doped with silicon would be manufactured by a different process than silicon carbide. The ratio between the carbon and silicon may locally vary throughout the structure. Carbon doped with silicon is also called silicon-doped carbon. For the same reasons, silicon doped with carbon is different than silicon carbide. Manufacturing items of high purity carbon doped with silicon is less expensive than manufacturing items of high purity silicon carbide. In some embodiments, the component body substrate without the dopant is 90% pure silicon or 90% pure carbon by mole percentage. It has been found that silicon doped with carbon, boron, tungsten molybdenum, or tantalum has a significantly increased fluorine or oxygen containing plasma erosion resistance and physical sputtering erosion resistance. In addition, it has been found that carbon doped with boron, tungsten molybdenum, silicon, or tantalum has a significantly increased fluorine or oxygen containing plasma erosion resistance and physical sputtering erosion resistance. Forming a part from silicon or carbon with a dopant is about the same cost as forming the part out of pure silicon or carbon, yet provides a part that is significantly more resistant to erosion by a fluorine or oxygen containing plasma and physical sputtering. In some embodiments, the component body 102 is made of boron.

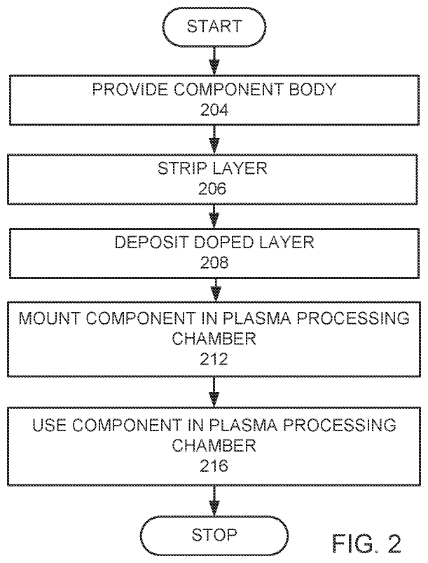

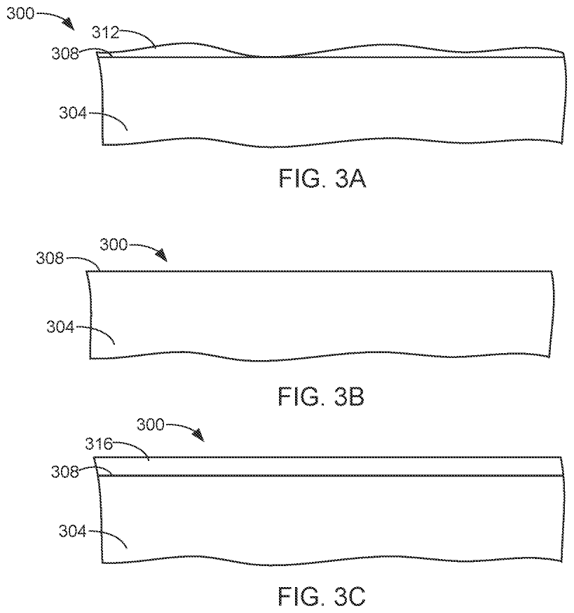

While some embodiments provide new components, other embodiments may be used to recondition plasma processing chamber parts. For example, FIG. 2 is a high level flow chart of a process used in another embodiment. A component body is provided (step 204). FIG. 3A is a schematic cross-sectional view of part of a component body 304 of a component 300 that is used in an embodiment. In this example, the component body 304 is a carbon component body. The component body substrate is made of carbon. The component body 304 has a semiconductor process facing surface. In this embodiment, the semiconductor process facing surface is a plasma facing surface 308. The plasma facing surface 308 is a part of the component body 304 that is adapted to face a plasma when the component body 304 is used in a plasma processing chamber. In this embodiment, the component 300 is a used plasma processing part. The component body 304 has a used coating layer 312. In this embodiment, some of the used coating layer 312 has been eroded so that the plasma facing surface 308 of the component body 304 is not covered by the used coating layer 312 and therefore is exposed to plasma during plasma processing.

In order to recondition the used component, the used coating layer 312 is first stripped from the component body 304 (step 206). In this example, the stripping of the used coating layer 312 may be by a machining process that at least mechanically removes the used coating layer 312. A chemical or plasma stripping may be used to further remove the used coating layer 312. FIG. 3B is a schematic cross-sectional view of part of a component body 304 after the used coating layer 312 (shown in FIG. 3A) is stripped to expose the plasma facing surface 308 of the component body 304. In some embodiments, some of the component body 304 is stripped. In other embodiments, some of the used coating layer 312 is not stripped away.

Next, the plasma facing surface 308 is coated by a carbon layer doped with tantalum. In this embodiment, chemical vapor deposition (CVD) is used to deposit the carbon layer doped with tantalum. FIG. 3C is a schematic cross-sectional view of part of a component body 304 after a layer 316 has been deposited on the plasma facing surface 308 of the component body 304. Additional machining and cleaning steps may be provided to further process the layer 316 and component body 304 and to provide a desired surface finish. In this embodiment, the layer 316 has a thickness in the range of 5 μm to 3 mm.

The component body 304 is mounted in a plasma processing chamber (step 212). In this example, the component body 304 is mounted in the plasma processing chamber as a liner. The plasma processing chamber is used to process a process wafer (step 216), where a plasma is created within the chamber to process a process wafer, such as etching the process wafer, and the layer 316 is exposed to the plasma. The layer 316 provides increased etch resistance to protect the plasma facing surface 308 of the component body 304.

In some embodiments, a component body 304 is provided (step 204) as part of a new component so that there is no layer over the plasma facing surface 308 of the component body 304. In such embodiments, the stripping of the layer (step 206) is skipped. A doped layer is deposited on the plasma facing surface 308 of the component body 304 (step 208).

Other embodiments may use other methods of depositing a doped carbon or silicon layer. In an embodiment, alternating layers of silicon or carbon and layers of a dopant may provide a laminated layer of alternating laminate layers of silicon or carbon layers and dopant layers. Such a laminated layer may provide a silicon or carbon layer doped with a dopant. In some embodiments, the alternating laminate layers may each have an atomic or molecular monolayer thickness. In other embodiments, the alternating laminate layers may have a thickness in the range of 0.1 μm to 100 μm.

In other embodiments, a thermal spray is used to deposit carbon or silicon doped with a dopant. One example of a thermal spray process is atmospheric plasma spraying. Atmospheric plasma spraying is a type of thermal spraying in which a torch is formed by applying an electrical potential between two electrodes, leading to ionization of an accelerated gas (a plasma). Torches of this type can readily reach temperatures of thousands of degrees Celsius, liquefying high melting point materials such as ceramics. Particles of carbon or silicon and a dopant of tantalum are injected into the jet, melted, and then accelerated towards the process wafer so that the molten or plasticized material coats the surface of the component and cools, forming a solid, conformal coating. In some embodiments, the thermal spraying provides a layer with a thickness in the range of 30 μm to 200 μm. Various embodiments may use various spraying processes, such as at least one of thermal spray processes such as wire arc spraying, air plasma spraying, atmospheric plasma spraying, suspension plasma spraying, low-pressure plasma spraying, and very low-pressure plasma spraying. Other spraying processes may be cold spraying, kinetic energy spraying, and aerosol deposition.

The film thickness will depend largely on the material of the substrate and the material of the coating. A deposited metal film behaves differently from a deposited ceramic film. In addition, switching between a ceramic or metal substrate will have a significant impact as will surface roughness, surface chemistry, and part geometry may also be factors in film thickness. Generally, a thermal spray coating may have a thickness of 0.01 mm to 3 mm. An atmospheric plasma spray coating may have a thickness of 0.1 μm to 1,000 μm. A suspension plasma spray coating may have a thickness of 0.1 μm to 200 μm. A high velocity oxygen fuel spray coating may have a thickness of 0.1 mm to 10 mm A cold spraying coating may have a thickness of 0.1 mm to 10 mm. An aerosol deposition coating for yttria has a thickness of 2 μm to 20 μm. In other embodiments, chemical vapor deposition (CVD) or plasma-enhanced chemical vapor deposition (PECVD) processes may be used to deposit a carbon or silicon doped layer.

In some embodiments, heavier dopants such as tungsten, tantalum, and molybdenum may be advantageous in conditions where heavier dopants provide improved etch resistance. In other embodiments, boron would provide more etch resistance in an oxygen containing plasma.

In another embodiment, a boron layer is plasma sprayed on a carbon or silicon surface forming a boron layer with a thickness of at least 1 mm. In some embodiments, the boron layer has a thickness in the range of 0.01 mm to 5 mm. In some embodiments, for a C-shroud chamber liner, the coating thickness may be in the range of 0.01 μm to 200 μm. For an edge ring, a coating may have a thickness in the range of 200 μm to 10 mm Other embodiments provide a boron layer over an aluminum body. In this embodiment, the boron layer is plasma etch and sputtering resistant. In other embodiments, a layer of at least one of boron, tungsten, molybdenum, and tantalum coats a plasma facing surface. In some embodiments, the component body may comprise at least one of quartz, aluminum, silicon, and carbon.

In other embodiments, refurbishing a used layer may involve baking out dopants and redoping a layer. In other embodiments, an acid etch may be used to remove a layer before depositing a new doped layer. In other embodiments, a used layer may not be stripped. Instead, a new layer may be deposited on the used layer. The new layer would then undergo a surface finish process such as machining, cleaning, or chemical treatment.

In other embodiments, a coating may be applied by at least one of thermal spraying, aerosol deposition, additive manufacturing, and polymer conversion. Aerosol deposition is achieved by passing a carrier gas through a fluidized bed of solid powder mixture. Driven by a pressure difference, the powder mixture particles are accelerated through a nozzle, forming an aerosol jet at its outlet. The aerosol is then directed at the plasma facing surface 308 of the component body 304, where the aerosol jet impacts the surface with high velocity. The particles break up into solid nanosized fragments, forming a coating. In some embodiments, a coating deposited by aerosol deposition would have a thickness in the range of 2 μm to 10 μm.

In various embodiments, the component body is silicon or carbon doped with 0.01% to 50% by mole percentage of at least one of boron, tungsten, molybdenum, and tantalum. The component body may be made by sintering a powder of silicon or carbon with a dopant. In some embodiments, a green part or partially sintered part may be machined and then a final anneal may be used to densify the component body. The component body may be made by 3D printing or another additive manufacturing process. Other embodiments use hot pressing or hot isostatic pressing to form the component body. In other methods, fusion, such as flame fusion or plasma fusion used to form fused silica parts may be used to form the component body. For example, such fusion may be used to make a component body of silicon with a dopant. In other embodiments, CVD may be used to form the part in a near-net shape by using a graphite mandrel that is later removed to grow the material into a shape close to the final part dimensions. In other embodiments, a graphite mold may be used to sinter the parts into a near-net shape during sintering. Other embodiments may form a C-shaped body by polymer conversion, where a polymer is graphitized through some combinations of heating in oxidizing or reducing conditions. In some embodiments, a component is designed to be significantly etched away over the component lifetime. In such embodiments, the component body is doped, so that as the component is etched away the dopant continues to provide etch resistance.

In some embodiments, silicon or carbon is doped with a dopant at a concentration in a range of 0.01% to 30%. In some embodiments, silicon or carbon is doped with a dopant at a concentration in a range of 0.01% to 10%. In other embodiments, silicon or carbon is doped with a dopant at a concentration in a range of 0.5% to 5%. It has been found that a dopant concentration of 1% boron in carbon provides a significantly increased etch resistance to an oxygen plasma compared to undoped carbon.

In some embodiments, an in-situ reconditioning of a component is provided. In such an embodiment, after a process wafer is processed the process wafer is removed. A PECVD process is used to deposit a silicon coating doped with tungsten on at least plasma facing surfaces of the plasma processing chamber. Then, another process wafer would be placed in the plasma processing chamber and the wafer would be processed in the plasma processing chamber. Such a conditioning may be provided after processing every process wafer or after processing a number of process wafers. Such a deposition provides a coating with increased plasma and physical sputtering resistance of the plasma facing surface of the component. By depositing the layer on the component in-situ, downtime may be reduced since the component does not need to be removed and then reinstalled in order to have a protective layer deposited.

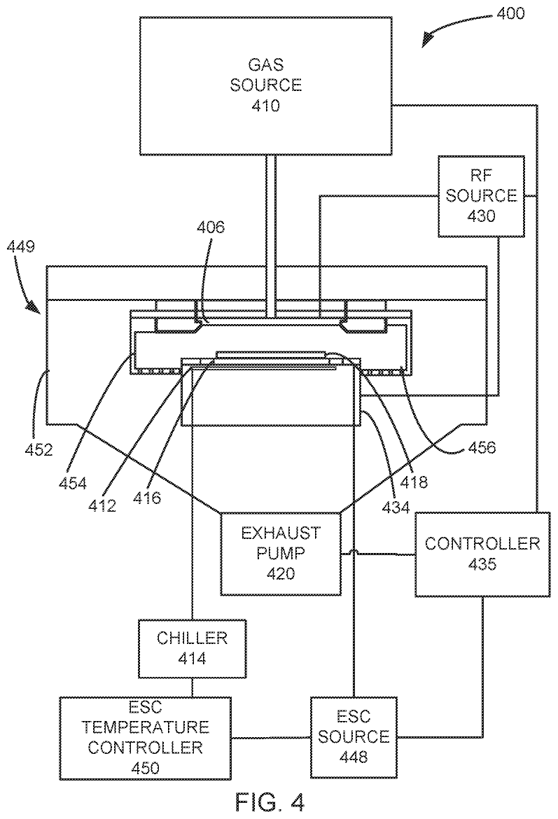

FIG. 4 is a schematic view of a semiconductor processing reactor that may be used in an embodiment. In one or more embodiments, semiconductor processing chamber 400 is an etch reactor comprising a gas distribution plate 406, in the form of a showerhead, providing a gas inlet and an electrostatic chuck (ESC) 434, within a plasma processing chamber 449, enclosed by a chamber wall 452. Within the plasma processing chamber 449, a wafer 416 is positioned over the ESC 434. The ESC 434 may provide a bias from the ESC source 448. An etch gas source 410 is connected to the plasma processing chamber 449 through the gas distribution plate 406. A C-shroud 454 forms a liner within the plasma processing chamber 449. The C-shroud 454 has a plurality of vents 456 to allow gas to pass from the gas distribution plate 406 through the plurality of vents 456 to an exhaust pump 420. An ESC temperature controller 450 is connected to a chiller 414. In this embodiment, the chiller 414 provides a coolant to channels 412 in or near the ESC 434. A radio frequency (RF) source 430 provides RF power to a lower electrode and/or an upper electrode. In this embodiment, the lower electrode is the ESC 434 and the upper electrode is the gas distribution plate 406. In an exemplary embodiment, 400 kilohertz (kHz), 60 megahertz (MHz), and optionally 2 MHz, 27 MHz power sources make up the RF source 430 and the ESC source 448. In this embodiment, the upper electrode is grounded. In this embodiment, one generator is provided for each frequency. In other embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments. A controller 435 is controllably connected to the RF source 430, the ESC source 448, the exhaust pump 420, and the etch gas source 410. An example of such an etch chamber is the Exelan Flex™ etch system manufactured by Lam Research Corporation of Fremont, CA.

In various embodiments, the component 300 may form the gas distribution plate 406, also called a showerhead electrode, and the C-shroud 454 or any other liner. Because the gas distribution plate 406 must have a plurality of apertures to provide for a flow of gas and the C-shroud 454 must have vents 456, the gas distribution plate 406 and the C-shroud 454 have a complex geometry that may require machining Therefore, the component body of the gas distribution plate 406 and the C-shroud 454 is made of a material that can be machined into a desired shape at a reasonable cost, in this embodiment.

In some embodiments, where a fluorine plasma is used, a component made of elements that produce volatile byproducts with the fluorine plasma causes reduced particle contamination. Such elements make a volatile byproduct with fluorine instead of making a solid byproduct, where the solid byproduct becomes a particle contaminant Carbon, boron, and silicon, form volatile byproducts with fluorine. Byproducts of tungsten, molybdenum, and tantalum with fluorine are able to be vaporized using plasma processing temperatures of less than 100° C. In some embodiments, where an oxygen plasma is used, a component made of elements that produce volatile byproducts with the oxygen plasma causes reduced particle contamination. Such elements make a volatile byproduct with oxygen instead of making a solid byproduct, where the solid byproduct becomes a particle contaminant Carbon forms volatile byproducts with oxygen.

It has also been found that carbon, silicon, and boron are highly resistant to physical sputtering. Physical sputtering resistance is particularly important for dielectric chambers where a high ion energy is used to control the ion angular distribution. Reactive ion etching at high biases results in significant physical bombardment, not only on wafer but also of the plasma-exposed chamber components. Although carbon has the highest physical sputtering erosion resistance, carbon is vulnerable to erosion by an oxygen containing plasma. By adding a dopant of B, W, Si, Mo, or Ta, the resistance of carbon against erosion by an oxygen containing plasma is increased. When subjected to an oxygen plasma these dopants form nonvolatile oxides that are sputter resistant. Some embodiments may be carbon with boron and nitrogen dopants.

It has been found that both Si and C doped with one or more of C, B, W, Si, Mo, and Ta is etch-resistant. The etch rate of C can be high in reactive etch plasmas containing oxygen radicals, and doping improves the etch resistance. Similarly, the etch resistance of Si in high physical bombardment conditions can be poor compared to C or B, and forming a composition containing Si and B can improve overall etch resistance. It has been found that boron provides both the high inherent resistance to physical bombardment as well as resistance to oxygen chemistries.

In various embodiments, the component body or layer has a sufficiently high thermal and electrical conductivity, a reasonable coefficient of thermal expansion, and enough hardness and flexural modulus to satisfy mechanical constraints. Various embodiments have unique advantages depending on the characteristics of the reactive etch plasma. Some compositions will be chosen for physical bombardment, while others would be chosen for oxygen or fluorine resistance. Various embodiments provide a composition that maximizes part lifetime by balancing tradeoffs between oxygen, fluorine, and physical bombardment resistance.

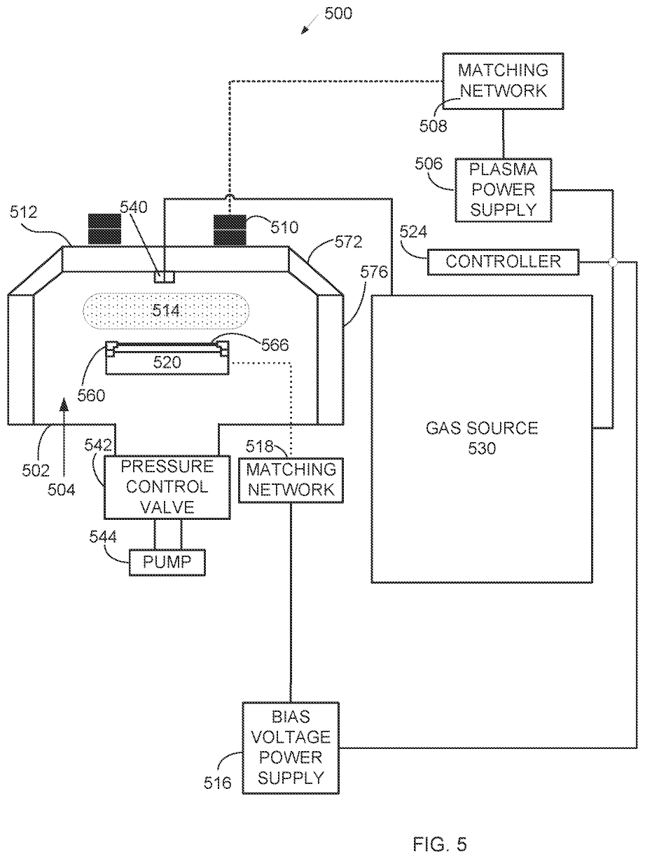

FIG. 5 schematically illustrates an example of another plasma processing chamber system 500 that may be used in another embodiment. The plasma processing chamber system 500 includes a plasma reactor 502 having a plasma processing confinement chamber 504 therein. A plasma power supply 506, tuned by a plasma matching network 508, supplies power to a transformer coupled plasma (TCP) coil 510 located near a dielectric inductive power window 512 to create a plasma 514 in the plasma processing confinement chamber 504 by providing an inductively coupled power. A pinnacle 572 extends from a chamber wall 576 of the plasma processing confinement chamber 504 to the dielectric inductive power window 512 forming a pinnacle ring. The pinnacle 572 is angled with respect to the chamber wall 576 and the dielectric inductive power window 512, such that the interior angle between the pinnacle 572 and the chamber wall 576 and the interior angle between the pinnacle 572 and the dielectric inductive power window 512 are each greater than 90° and less than 180°. The pinnacle 572 provides an angled ring near the top of the plasma processing confinement chamber 504, as shown. The TCP coil (upper power source) 510 may be configured to produce a uniform diffusion profile within the plasma processing confinement chamber 504. For example, the TCP coil 510 may be configured to generate a toroidal power distribution in the plasma 514. The dielectric inductive power window 512 is provided to separate the TCP coil 510 from the plasma processing confinement chamber 504 while allowing energy to pass from the TCP coil 510 to the plasma processing confinement chamber 504. The TCP coil 510 acts as an electrode for providing RF power to the plasma processing confinement chamber 504. A wafer bias voltage power supply 516 tuned by a bias matching network 518 provides power to an electrode 520 to set the bias voltage on the process wafer 566. The process wafer 566 is supported by the electrode 520 so that the electrode acts as a substrate support. A controller 524 controls the plasma power supply 506 and the wafer bias voltage power supply 516.

The plasma power supply 506 and the wafer bias voltage power supply 516 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 506 and wafer bias voltage power supply 516 may be appropriately sized to supply a range of powers in order to achieve desired process performance. For example, in one embodiment, the plasma power supply 506 may supply the power in a range of 50 to 5000 Watts, and the wafer bias voltage power supply 516 may supply a bias voltage of in a range of 20 to 2000 volts (V). In addition, the TCP coil 510 and/or the electrode 520 may be comprised of two or more sub-coils or sub-electrodes. The sub-coils or sub-electrodes may be powered by a single power supply or powered by multiple power supplies.

As shown in FIG. 5, the plasma processing chamber system 500 further includes a gas source/gas supply mechanism 530. The gas source 530 is in fluid connection with plasma processing confinement chamber 504 through a gas inlet, such as a gas injector 540. The gas injector 540 may be located in any advantageous location in the plasma processing confinement chamber 504 and may take any form for injecting gas. Preferably, however, the gas inlet may be configured to produce a “tunable” gas injection profile. The tunable gas injection profile allows independent adjustment of the respective flow of the gases to multiple zones in the plasma process confinement chamber 504. More preferably, the gas injector is mounted to the dielectric inductive power window 512. The gas injector may be mounted on, mounted in, or form part of the power window. The process gases and by-products are removed from the plasma process confinement chamber 504 via a pressure control valve 542 and a pump 544. The pressure control valve 542 and pump 544 also serve to maintain a particular pressure within the plasma processing confinement chamber 504. The pressure control valve 542 can maintain a pressure of less than 1 torr during processing. An edge ring 560 is placed around the process wafer 566. The gas source/gas supply mechanism 530 is controlled by the controller 524. A Kiyo by Lam Research Corp. of Fremont, CA, may be used to practice an embodiment.

In various embodiments, the component may be other parts of a plasma processing chamber, such as confinement rings, edge rings, the electrostatic chuck, ground rings, chamber liners, door liners, the pinnacle, gas injectors, windows, or other components. Other components of other types of plasma processing chambers may be used in other embodiments. For example, plasma exclusion rings on a bevel etch chamber may be coated in an embodiment. In some embodiments one or more, but not all surfaces are doped. The component may be made of a ceramic material, metal, or a dielectric material.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A component for use in a semiconductor processing chamber, comprising:
a component body; and
a semiconductor process facing surface of the component body adapted to face a semiconductor process in the semiconductor processing chamber, wherein the semiconductor process facing surface, comprises 1) a layer of silicon doped with a dopant wherein the dopant is at least one of carbon, boron, tungsten, molybdenum, and tantalum, wherein the dopant has a concentration that ranges from 0.01% to 50% by mole percentage, or 2) a layer of carbon doped with a dopant wherein the dopant is at least one of silicon, boron, tungsten, molybdenum, and tantalum, wherein the dopant has a concentration that ranges from 0.01% to 50% by mole percentage, or 3) a layer consisting essentially of boron, or 4) a layer consisting essentially of tantalum.

2. The component, as recited in claim 1, wherein the component body forms at least one of a liner, electrode, gas injector, showerhead electrode, confinement ring, and edge ring of the semiconductor processing chamber.

3. The component, as recited in claim 1, wherein the component body is a silicon, boron, or carbon component body substrate.

4. The component, as recited in claim 3, wherein the component body is doped with a dopant, wherein the dopant is at least one of boron, tungsten, molybdenum, and tantalum, wherein the dopant in the component body has a concentration that ranges from 0.01% to 50% by mole percentage.

5. The component, as recited in claim 3, wherein the component body substrate without the dopant is 90% pure silicon or 90% pure carbon by mole percentage.

6. The component, as recited in claim 1, wherein the layer has a thickness in a range of 0.001 mm to 25 mm.

7. The component as recited in claim 1, wherein the layer is silicon, doped with boron, and wherein the component body is silicon.

8. The component, as recited in claim 1, wherein the component body comprises aluminum.

9. The component, as recited in claim 1, wherein the layer comprises a plurality of laminate layers.

10. A method for providing a component for use in a semiconductor processing chamber, comprising forming a layer on a semiconductor process facing surface of the component wherein 1) the layer comprises silicon doped with a dopant wherein the dopant is at least one of carbon, boron, tungsten, molybdenum, and tantalum, wherein the dopant has a concentration that ranges from 0.01% to 50% by mole percentage, or wherein 2) the layer comprises carbon doped with a dopant wherein the dopant is at least one of silicon, boron, tungsten, molybdenum, and tantalum, wherein the dopant has a concentration that ranges from 0.01% to 50% by mole percentage, or wherein 3) the layer consists essentially of boron or tantalum.

11. The method, as recited in claim 10, further comprising stripping part of the semiconductor process facing surface before forming the layer on the semiconductor process facing surface.

12. The method, as recited in claim 11, wherein the component is a used component and wherein the stripping part of the semiconductor process facing surface strips a used layer on the semiconductor process facing surface.

13. The method, as recited in claim 10, wherein the forming the layer on the semiconductor process facing surface, comprises growing a silicon layer or carbon layer on the semiconductor process facing surface, wherein the silicon layer or carbon layer is doped with the dopant.

14. The method, as recited in claim 10, wherein the forming the layer on the semiconductor process facing surface comprises forming the component from silicon doped with a dopant wherein the dopant is at least one of carbon, boron, tungsten, molybdenum, and tantalum or forming the component from carbon doped with a dopant wherein the dopant is at least one of boron, tungsten, molybdenum, silicon, and tantalum.

15. The method, as recited in claim 10, forming the layer comprises using at least one of chemical vapor deposition, plasma-enhanced chemical vapor deposition, sintering, thermal spraying, aerosol deposition, additive manufacturing, and polymer conversion.

16. The method, as recited in claim 10, wherein the layer and component are formed by doping a molten silicon and then solidifying the molten silicon.

17. The method, as recited in claim 10, wherein the forming the layer on a semiconductor process facing surface of the component is performed in-situ when the component is mounted in the semiconductor processing chamber and wherein the semiconductor processing chamber is used to process a process wafer before forming the layer on the semiconductor process facing surface of the component and is used to process another process wafer after forming the layer on the semiconductor process facing surface.

18. A component for use in a semiconductor processing chamber, comprising:
a component body with a semiconductor process facing surface; and
a coating of at least one of boron, tungsten, molybdenum, and tantalum on the semiconductor process facing surface.

19. A method for conditioning a component body with a semiconductor process facing surface for use in a semiconductor processing chamber, comprising forming a layer, comprising at least one of boron, tungsten, molybdenum, and tantalum over the semiconductor process facing surface of the component body.

20. The method, as recited in claim 19, further comprising stripping part of the semiconductor process facing surface before forming the layer on the semiconductor process facing surface.

21. The method, as recited in claim 20, wherein the component body is part of a used component and wherein the stripping part of the semiconductor process facing surface strips a used layer on the semiconductor process facing surface.

22. The method, as recited in claim 19, wherein the forming the layer on the semiconductor process facing surface, comprises 1) growing a silicon layer on the semiconductor process facing surface, wherein the silicon layer is doped with at least one of carbon, boron, tungsten, molybdenum, and tantalum or 2) growing a carbon layer on the semiconductor process facing surface, wherein the carbon layer is doped with at least one of silicon, boron, tungsten, molybdenum, and tantalum.

23. The method, as recited in claim 19, wherein the forming the layer is performed in-situ when the component body is mounted in the semiconductor processing chamber and wherein the semiconductor processing chamber is used to process a process wafer before forming the layer over the semiconductor process facing surface of the component body and is used to process another process wafer after forming the layer over the semiconductor process facing surface.

24. A semiconductor processing chamber for processing substrates, comprising:
a semiconductor process chamber;
a substrate support within the semiconductor process chamber;
a gas inlet for delivering gases into the semiconductor process chamber;
a gas source for providing the gases to the gas inlet;
an electrode for providing RF power in the semiconductor process chamber; and
at least one RF generator, for providing power to the electrode to form a plasma in the semiconductor processing chamber, wherein a surface within the semiconductor process chamber is a semiconductor process facing surface, and wherein the semiconductor process facing surface, comprises 1) a layer of silicon doped with a dopant wherein the dopant is at least one of carbon, boron, tungsten, molybdenum, and tantalum, wherein the dopant has a concentration that ranges from 0.01% to 50% by mole percentage, or 2) a layer of carbon doped with a dopant wherein the dopant is at least one of silicon, boron, tungsten, molybdenum, and tantalum, wherein the dopant has a concentration that ranges from 0.01% to 50% by mole percentage, or 3) a layer consisting essentially of boron, or 4) a layer consisting essentially of tantalum.
